(19) United States
(12) Patent Application Publication
(10) Pub. No.: US 2015/0091546 A1
(43) Pub. Date: Apr. 2, 2015

(54) POWER MEASUREMENT ANALYSIS OF PHOTOVOLTAIC MODULES

(71) Applicant: TEL Solar AG, Trubbach (CH)

(72) Inventor: Ralf Adelhelm, Freiburg (DE)

(73) Assignee: TEL Solar AG, Trubbach (CH)

(21) Appl. No.: 14/284,515

(22) Filed: May 22, 2014

Related U.S. Application Data
(60) Provisional application No. 61/883,208, filed on Sep. 27, 2013.

(51) Int. Cl. G01R 31/40

(52) U.S. Cl. CPC G01R 31/405
USPC 324/76.11

(57) ABSTRACT

A method of measuring a current-voltage (IV) characteristic for a photovoltaic (PV) device is described. The method includes providing a PV module for measuring an IV characteristic; exposing the PV module to a solar electromagnetic (EM) spectrum; and acquiring an IV data point on the IV characteristic. The acquisition of an IV data point includes measuring plural IV segments by repetitively applying and sweeping a voltage across the PV module from a unique initial voltage to a target voltage within a time scale for exposing said PV module to the solar EM spectrum, and interpreting a measured current at the target voltage as the IV data point on the IV characteristic if the plural IV segments converge at the target voltage.

### CROSS-REFERENCE TO RELATED APPLICATIONS

Pursuant to 37 C.F.R. §1.78(a)(4), this application claims the benefit of and priority to co-pending U.S. Provisional Application No. 61/883,208, filed on Sep. 27, 2013, which is expressly incorporated by reference herein in its entirety.

### BACKGROUND OF THE INVENTION

1. Field of Invention

The invention relates to a method for measurement and characterization of photovoltaic (PV) modules.

2. Description of Related Art

Where the conventional crystalline silicon photovoltaic (PV) technology gains from decades of experience in metrology, the thin-film silicon photovoltaics are confronted with the challenges of tandem devices, new spectral requirements, the lack of reference solar cells, and a high number of inadequate test methods. In consequence, conventional solutions for indoor measurements do not lead to certified reference modules to date.

### SUMMARY OF THE INVENTION

Embodiments of the invention relate to a method for measurement and characterization of photovoltaic (PV) modules. For example, the measurement method is applicable to crystalline silicon PV devices, thin film PV devices, including thin film silicon PV devices, and hetero-junction (HJT) PV devices.

According to one embodiment, a method of measuring a current-voltage (IV) characteristic for a photovoltaic (PV) device is described. The method includes providing a PV module for measuring an IV characteristic; exposing the PV module to a solar electromagnetic (EM) spectrum; applying and sweeping a voltage across the PV module from a first initial voltage to a first target voltage, and measuring and recording a first current for the PV module at the first target voltage; and characterizing the PV module by calculating PV module power or assembling a PV module IV characteristic using the measured first current corresponding to the first target voltage.

According to another embodiment, a method of measuring a current-voltage (IV) characteristic for a photovoltaic (PV) device is described. The method includes providing a PV module for measuring an IV characteristic; exposing the PV module to a solar electromagnetic (EM) spectrum; and acquiring an IV data point on the IV characteristic. The acquisition of an IV data point includes measuring plural IV segments by repetitively applying and sweeping a voltage across the PV module from a unique initial voltage to a target voltage within a time scale for exposing said PV module to the solar EM spectrum, and interpreting a measured current at the target voltage as the IV data point on the IV characteristic if the plural IV segments converge at the target voltage.

According to yet another embodiment, a method of measuring a current-voltage (IV) characteristic for a photovoltaic (PV) device is described. The method includes providing a PV module for measuring an IV characteristic; exposing the PV module to a solar electromagnetic (EM) spectrum; performing a first set of measurements that includes acquiring plural IV segments by applying and sweeping a voltage across the PV module beginning from a first series of unique initial voltages and ending at a first target voltage within a first time scale for exposing said PV module to the solar EM spectrum; and measuring and recording a first current for the PV module at the first target voltage if convergence of the plural IV segments in the first set of measurements occurs at the first target voltage.

### BRIEF DESCRIPTION OF THE DRAWINGS

In the accompanying drawings:

FIG. 1 depicts a typical IV characteristic for a PV device;

FIG. 2 depicts the current and voltage close to the V_{oc} over the time of the pulse plateau;

FIG. 3 depicts the fading V_{oc} of a first PV tandem module;

FIG. 4 depicts the fading V_{oc} of a second PV tandem module;

FIG. 5 depicts the fading maximum power point (MPP) of a third tandem module;

FIG. 6. depicts a first module current and irradiances;

FIG. 7. depicts a second module current and irradiances; and

FIG. 8. depicts a third module current and irradiances.

### DETAILED DESCRIPTION OF SEVERAL EMBODIMENTS

Methods for measuring and characterizing the performance of PV devices/modules are described in various embodiments. One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

On the road towards standardized electrical power measurement of tandem photovoltaic (PV) modules, the key instrumentation, a spectrally tunable large-area solar simulator, provides the appropriate adjustments to achieve the standard test conditions (STC). The measurement of the spectral irradiance is performed with primary calibrated spectrally selective component solar cells. Traceable flasher-based power measurements of tandem modules are completed with regard to an error analysis and a required solution for transient problems of fast measurements. An advanced multi-flashing procedure is introduced and described. Aside from the precise STC measurement in the sense of the calibration of reference modules, the spectral tuning allows deeper investigations with multiple current-voltage (IV) measurements as valuable feedback for the module design development. Such a spectrometric characterization of a series of modules with different bottom cell thicknesses results in the important assessment of the current matching of the tandem devices.

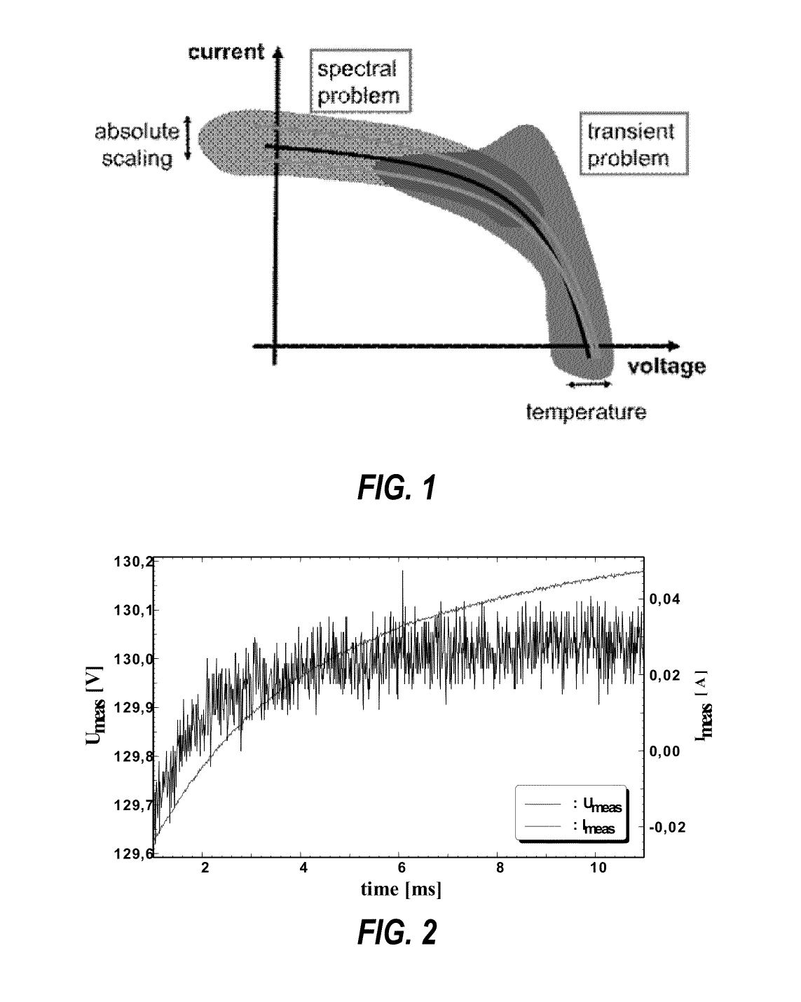

The precise power measurement of a PV module based on calibrated reference cells leads to a reference module with extremely low uncertainty in the electrical current-voltage (IV) characteristics. In fact, it is the correct determination at nominal Standard Test Conditions, which could be seen in direct relation to the present invention. In a simplified schema, the problems to be solved are illustrated, at least in part, in FIG. 1.

As shown in FIG. 1, the black line represents the true IV characteristics. The remaining elements in the figure illustrate the open issues of the fast IV curve measurement. The arrows and the colored fields indicate the possible variability.

A method for measurement and characterization of photovoltaic (PV) modules is described. For example, the measurement method is applicable to crystalline silicon PV devices, thin film PV devices, including thin film silicon PV devices, and hetero-junction (HJT) PV devices.

According to one embodiment, a method of measuring a current-voltage (IV) characteristic for a photovoltaic (PV) device is described. The method includes providing a PV module for measuring an IV characteristic; exposing the PV module to a solar electromagnetic (EM) spectrum; applying and sweeping a voltage across the PV module from a first initial voltage to a first target voltage, and measuring and recording a first current for the PV module at the first target voltage; and characterizing the PV module by calculating PV module power or assembling a PV module IV characteristic using the measured first current corresponding to the first target voltage.

The measurement method addresses: a.) the absolute scaling of the IV curve in the sense of nominal 1000 W/m²; b.) the “spectral problem” with its non-quantified influence; c.) temperature control, discussed below; and d.) the “transient problem” to be investigated for fast IV sweeping.

The uncertainty of PV device measurement is minimized by addressing, among other things, the problems with the following developments: a.) absolute scaling: development and use of primary calibrated component reference cells as each single junction solar cell represents the spectral response of the top or bottom sub cell; b.) spectral problem: development of a set-up with adjustable spectrum. In one embodiment, the method further includes: c.) temperature: high end control of the laboratory's temperature (see below); and d.) transient problem: development of an advanced multi-flashing method.

In addition to the STC measurements, the measurement output is expanded to spectrometric investigations, where the solar simulator works as diagnostic feedback for the module design development. Both the xenon flash lamp intensity variation and the control of the distance to the PV device give the spectrometric variability for an assessment of a tandem module.

The final error analysis of the STC measurement achieves the goal: the overall expanded uncertainty (k=2) of the tandem module power measurement shall be less than 3%.

To address the transient matter, during a fast sweep through an IV characteristic within the approximately 10 milliseconds of the stable flash pulse plateau, some transient reactions can affect the curve of all types of solar cells and require analysis and correction. In the special case that both sweep directions (forward: I_{sc}->V_{oc} and reverse: V_{oc}->I_{sc}) show no hysteresis, the absence of transient effects is assumed. The opening of the hysteresis (green field in FIG. 1), mainly understood as capacitor or varactor, is driven by the voltage ramp dU/dt, which is typically in the range of ±100V/10 ms=±10 kV/s. The “transient problem” has searched a metrologically correct solution for decades, so the present measurement method according to various embodiments enables the one-flash-solution.

A detailed review shows module-specific transient problems. With the highest possible accuracy as the goal, the inventor determined that it is critical whether the time-consuming multi-flashing is a reasonable method. With the state of the art multi-flashing, a series of individual IV data points (typically several tens) is collected pulse by pulse, resulting in the IV curve. The critical test for the required steady-state has to be calculated with the current and voltage over time as in FIG. 2.

As shown in FIG. 2, Current and voltage close to the V_{oc} over the time of the pulse plateau. The current (red line) does not reach the steady-state within the 10 ms.

In the case of this PV module, there is no steady-state of current reached in the time frame of the pulse plateau. As the operation point is near the V_{oc}, an additional spectral effect can be excluded. Some types of tandem modules seem to require a long pulse, which has been confirmed previously.

According to an embodiment, an advanced multi-flashing technique, referred to as a “fading procedure”, is described to reduce the critical voltage ramp drastically. The fading procedure shows reasonable results. One IV data point, for example near V_{oc} or MPP, is reached by a target voltage of the electrical load but starting at a slightly different voltage. This approach should normally give a small segment of the IV characteristic. By selecting the starting voltage, the voltage ramp comes down to 100V/s. The application of imposed voltage shifts of ±3 V, ±2 V, ±1 V, which provides a family of curves surrounding the target voltage. This fading procedure works like an electrical brake with a subsequent inspection of the skid marks.

The Pasan electrical load with 16 bit data acquisition supports the measurement of IV segments with imposed linear voltage ramps by free selection of start and end voltage.

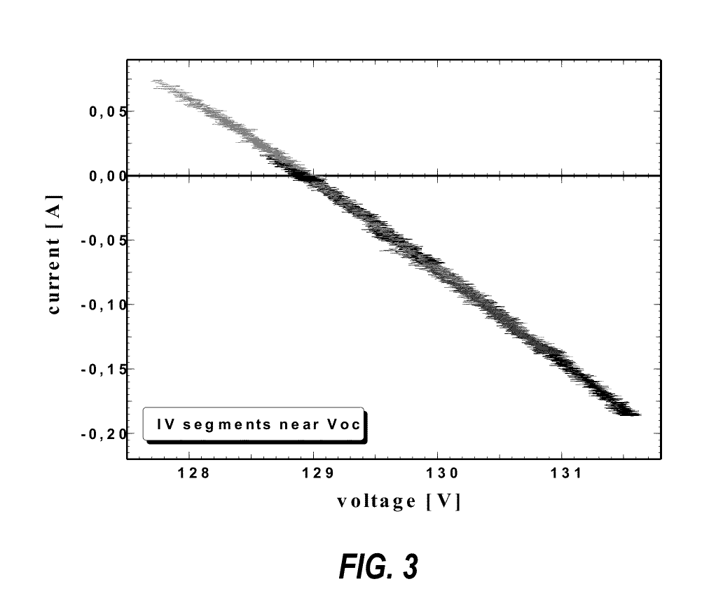

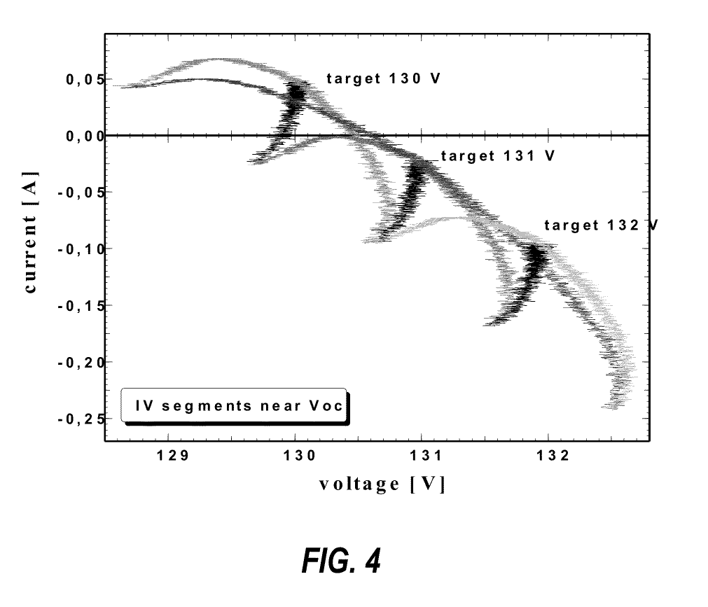

The experimental accuracy of an individual current-voltage data point of an IV curve, as produced by multi-flashing, can be increased by a family of IV curve segments. The series of short IV segments with low voltage ramps dU/dt shall end at the same voltage to prove the related current value. The following examples of IV segments near the open circuit voltage V_{oc} in FIGS. 3 and 4 demonstrate in an exemplary manner the fading procedure carried out with two tandem modules.

In FIG. 3, the fading V_{oc} of a first PV tandem module is shown. Each colored short IV segment is measured in a separated flash pulse. All segments together represent a part of the complete IV characteristics near the V_{oc}. No transient effect is observed in contrast to a different tandem module in FIG. 4.

In FIG. 4, the fading V_{oc} of a second PV tandem module is shown. The upper IV segments (green, red and blue, whereas red equals red in FIG. 2) result from three pulses with a target voltage of 130 V starting at 130V, 131V, 132V, respectively. The support of the second target voltage 131V is given by the convergence of five segments with voltage shifts from 0V, +/−1V, +/−2V. In summary, the three (five) endpoints support the quasi steady-state IV characteristics.

The target voltages for the interpolation of Voc are 129, 130, and 131 Volt. The target voltages are reached by three, five and a further three segments with voltage ramps in both directions. As the segments converge at each target voltage, the end point is interpreted as a data point of the quasi steady-state IV curve. Interestingly, with the second PV tandem module, the inventor found a seldom example of a significant transient effect in the V_{oc}, which would typically be misinterpreted as a temperature effect.

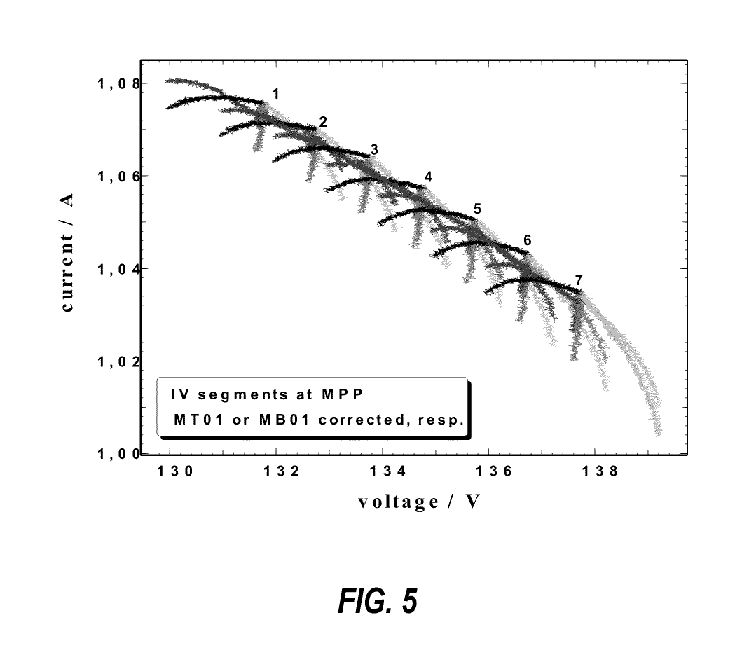

At the maximum power point (MPP), the fading procedure also has to be qualified with the successful convergence of the IV segments. FIG. 5 shows all IV segments recorded during a complete maximum power point fading procedure. For the MPP search, seven target voltages are reached by three ramps each. With the two corrections done by the component cells there are 42 segments in total.

In FIG. 5, the fading MPP of a third tandem module is shown. Each colored short IV segment is measured in a separate flash pulse and corrected by either the top or the bottom component cell. The endpoints of the segments 1-7 as an envelope result in the quasi steady-state IV characteristics at MPP.

Indeed, all the segments for one specific target voltage show convergence within 10 ms (milliseconds). In the ideal case, the convergence of the segments to the final IV data point is also attained at the best spectral balance of the flash light. It can be managed to shift the optimal spectral conditions to the end of the pulse plateau. The data base of the 42 segments (with both component cells) leads to high confidence in the MPP determination as shown in FIG. 5.

The fading procedure modifies the multi-flashing to a systematic study with low (linear) voltage ramps. The IV segments are selected in their start and end voltages to support the results of one specific IV data point with a specific target voltage. So, the known multi-flashing with the aim of only one data point at one target voltage is extended with small IV segments of positive (forward) and negative (reverse) voltage ramps applied during one-pulse measurements. As the (chronological) end of each segment indicates convergence, the asymptotic data points represent the quasi steady-state IV data points.

The fading procedure expands the multi-flashing to an enormous data base of IV segments requiring up to hundreds of measurements. With this huge data base, the limits for the best spectral match and the convergence lead to the data for the interpolation of I_{sc}, V_{oc} and Pₘₐₓ at MPP. The extraction of the IV parameter out of the data base shows statistically high confidence in the overall uncertainty of this procedure. This effort is justified by the value of the resulting reference module uncertainty. It seems so far that the module efficiency tends to be slightly underestimated in the case of typically complete IV curve measurement in 10 ms, but also depending on sweep direction of the regular IV curve.

Fading the short-circuit current I_{sc} shows generally no transient effects and reveals a linear behavior between the raw data of the device under test (DUT) current and both of the component cells. The results of the I_{sc} fading are cause for distrust in the irradiance correction procedure with only the one component cell, which represents the supposed limiting sub cell of the DUT. Only at the crossing of the component cells' actinic irradiances within the pulse, the DUT current can be used for further I_{sc} determination. This is an important argument for the high priority to match STC in such a precision as reported previously.

In addition to the STC measurement, the spectrally tunable solar simulator helps to diagnose the tandem structure of the tandem large-area module. The set-up, with its longitudinal sliding test bed for the references and the PV module, offers the opportunity for an investigation of the multiple IV characteristics at different spectra. The more than two meters variation and the sophisticated lamp intensity regulation give a range of blue-rich to red-rich spectra. The variation of the spectral distribution leads to the variation of the sub cell's currents, which finally results in the variation of the current-voltage characteristics.

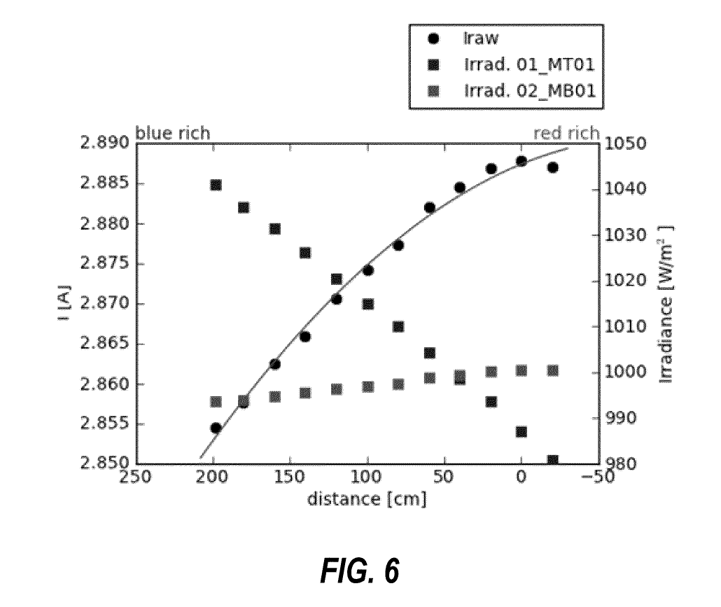

A preferred symmetrical spectral balancing around the reference spectrum AM1.5 would convey clear results. The gradient of the spectral shift for the top component cell signal with +2.8% per meter is an order of magnitude higher than that of the bottom component cell (−0.35%/m), so with increasing distance the blue section of the spectrum grows much faster than the red one decreases (FIG. 6). The actinic irradiances Gₜₒₚ and G_{bottom} are scaled with the component cell top (MT01) and bottom (MB01) with 1000 W/m² which equals the calibration value at STC. Those values are suitable to quantify a scale for the spectral balance, for example as a quotient Gₜₒₚ/G_{bottom}. Other spectrometric measures such as the average photon energy could also give a basis to relate IV curve parameters on a spectral scalar scale. In our case, the distance is used as a scale, and the blue rich side on the left is arranged with a decreasing distance. The measured actinic irradiances show explicitly the asymmetric balancing, which does not affect the significance of the results.

In one study, a series of five modules with constant top thicknesses and bottom cell thicknesses of 700 nm, 900 nm, 1000 nm, 1100 nm, and 1300 nm is manufactured and evaluated. The spectrometric investigation of each module covers the measured electrical data at 12 distances.

The results for the latest three modules are shown in FIGS. 6, 7 and 8. The actinic irradiances of the top (marked blue) and the bottom component cells (marked red) over the scale of the distance carry the actual spectral information and have a high reproducibility when compared to all figures. The discussion can be focused on the shape of the black marked module currents (green trend line) depending on the module's bottom cell thicknesses.

In FIG. 6, a first module (B1000) current (raw data at I_{sc}, black dots with green trend line) increases monotonically such as the bottom component signal and therefore the bottom cell is limiting. The interception of the actinic irradiances (blue and red) at 1000 W/m² and at distance of 40 cm marks the standard test conditions STC.

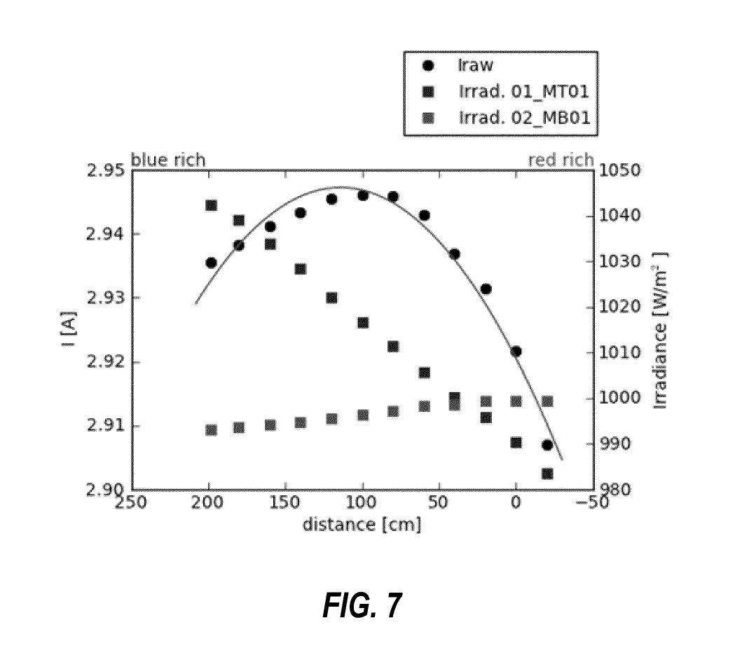

In FIG. 7, a second module (B1100) current and irradiances over the distance is shown. (The number in the module names gives the thickness of the bottom cell in nanometer.) The black dotted module current changes from bottom to top limitation at the maximum of the curve and is top cell limited at STC (40 cm distance).

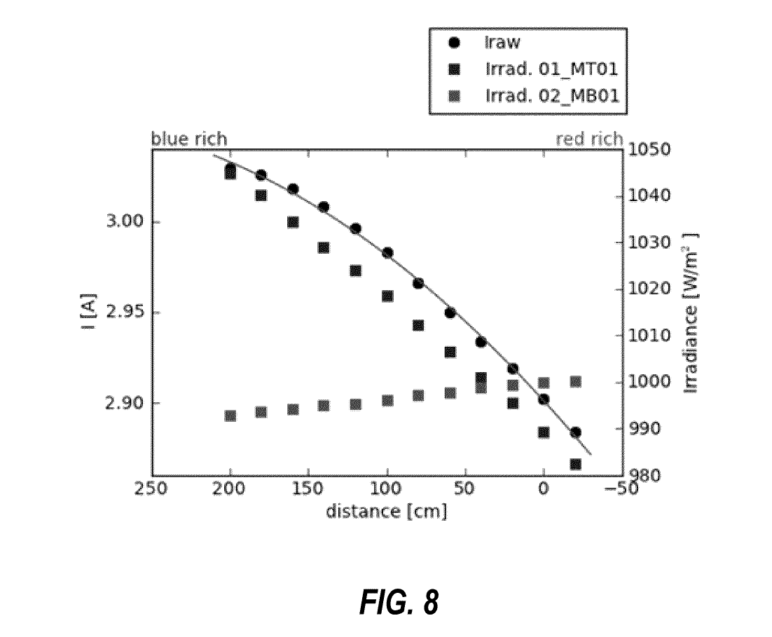

In FIG. 8, a third module (B1300) current and irradiances over the distance is shown. The high reproducibility of the spectral variation can be seen with comparison of all the irradiances of FIGS. 6 to 8. As the current (raw data near I_{sc}) follows the top component cell the module is top cell limited.

All kinds of current limitations are found within the set of five modules (Table I).

The assessment of the current matching is given with the three cases found in FIGS. 6 to 8: (a) the increasing, (b) change from increasing to decreasing, and (c) decreasing current revealing the three cases (a) the bottom cell limitation for B1000, (b) the change from bottom to top limitation for B1100, and (c) the top cell limitation for the module B1300.

The two modules B700 and B900 are comparable to B1000 at lower currents (Table I). The results are used as valuable feedback for the module design development. Further information can be gained from the behavior of the other IV parameters.

First of all, the solar simulator installation and the developed procedures are in full compliance with the known state-of-the-art metrology according to the existing IEC standards for reference cells, as well as single-junction PV devices and further for multi-junction PV devices (ASTM E2236).

The modified solar simulator Pasan SunSim IIIb, its spectral adjustment, and the method of using traceable reference component cells were published in J. Meier, R. Adelhelm, M. Apolloni, K. Keller, Z. Seghrouchni, D. Romang, S. Benagli, U. Kroll, “Traceable flasher-based power measurements of Micromorph tandem modules”, 26th EU PVESC, Hamburg, 2011.

TABLE I
Spectrometric investigated modules

| Module, the bottom | current raw | limitation within | |
|---|---|---|---|
| cell thickness in nm | data | spectral variation | limitation at STC |
| B700 | increasing, | bottom limited | bottom limited |
| | not shown | | |
| B900 | increasing, | bottom limited | bottom limited |
| | not shown | | |
| B1000 | increasing, | bottom limited | bottom limited |
| | FIG. 6 | | |
| B1100 | change, | change from | top limitation |
| | FIG. 7 | bottom to top | |
| | | limitation | |
| B1300 | decreasing, | top limitation | top limitation |
| | FIG. 8 | | |

Further, the specialization of the tandem technology with its spectral and transient problems is recognized with the addressed developments. It can be seen that both of these solutions reduce errors by an order of magnitude, from percent down to parts per thousand.

Currently, the uncertainty analysis of the calibration of a tandem module shows the qualification of the procedure to obtain reference modules with uncertainties (k=2) of 2.9% at maximum power at STC.

During calibration, in a first step, the primary calibrated reference component cells are installed at the central beam axis of the solar simulator to reach the best technical conditions for STC (distance, lamp intensity, alignment, etc.). Below the beam axis, under the module's position, the monitor component cells MT01 and MB01 are measured for further use (monitor cell calibration). In a second step, the (small) reference component cells are replaced by the device under test, the PV module. The transfer relative to the different sizes (active areas) is supported by the first-class uniformity of our simulator with both spectral sections (MT01: 0.75% and MB01: 0.27%). Then the module IV data are recorded with a series (up to hundreds) of flashes using (1) standard forward/reverse measurements, (2) multi-flashing and (3) the fading procedure for I_{sc}, V_{oc}, Pₘₐₓ.

Within data analysis those values are found by interpolation selecting the data with minimal deviations from STC.

With respect quality and assurance, the target accuracy requires detailed features in the laboratory: (1) the highly sophisticated laboratory temperature regulation leads to 25.0° C.±0.5° C. with spatial non-uniformity of 0.1° C. on the module, (2) the Instrument Systems UV/VIS/NIR array spectrometer with optical probe and high-speed shutter, (3) reviewed, renewed and applied calibration procedure of the electrical load, (4) upgraded 16 bit resolution during non-uniformity measurement, (5) parallel acquisition of 4 irradiance channels while using different component cells, (6) reference component cells' non-ideal behavior: measurement of angular dependency of incidence light (AOI) and appropriate correction of AOI during non-uniformity measurement, and (7) routine measurements of modules with different technologies routine monitor cell calibration.

The uncertainty analysis is guided by H. Müllejans, W. Zaaiman, R. Galleano, “Analysis and Mitigation of Measurement Uncertainties in the Traceability Chain for Calibration of Photovoltaic Devices”, Meas. Sci. Technol. 20, 2009, 075101, on the calculation of their measurements. The inventor added further items, ending up with 32 items. The main reasons are as follows: (1) the use of the monitor component cells in between the primary calibrated cell and the device under test, (2) transient effects, (3) spectral effects, and (4) detailed optical characteristics. The first exercise followed the known break down of the maximal power with:

P_{STC}=C(ref)×Pₘₐₓ=C(ref)×I_{sc}×V_{oc}×FF (1),

where C(ref) accumulates all influences resulting from the reference cells as pre-measurement correction. For the result of the fill factor (FF) the final IV characteristics has to be declared. But, the direct calculation via:

P_{STC}=C(ref)×Pₘₐₓ=C(ref)×Iₘₚₚ×Vₘₚₚ (2),

allows the use of the statistic resulting from the fading procedure. This approach produces a lower uncertainty for Pₘₐₓ at STC, which is declared in Table II.

TABLE II
Uncertainty of power measurement at STC

| | | | |
|---|---|---|---|
| Error sources | C (ref) | Pₘₐₓ | P_{STC} |

| | | | |
|---|---|---|---|
| I | Electrical | | |
| | Data acquisition, | | |
| | incl. Monitor | 0.32% | 0.19% |
| | transient effect | 0.05% | 0.21% |
| | remainder | 0.05% | 0.15% |
| II | Temperature | 0.01% | 0.10% |
| III | Optical | | |
| | non-uniformity | 0.20% | 0.60% |
| | remainder | 0.19% | 0.16% |
| IV | Spectrum | 1.10% | 0.00% |
| V | Reference cell | | |
| | calibration | 0.43% | |
| | remainder | 0.11% | 0.01% |

| | | | |
|---|---|---|---|
| standard uncertainty | 1.26% | 0.71% | 1.44% |
| (k = 1) | | | |
| expanded uncertainty | | | 2.89% |
| (k = 2) | | | |

The analysis covers the difficult case of transient modules such as seen in FIG. 5, and is still conservative with regards to the errors introduced by the spectrum and the non-uniformity. The excellent non-uniformity for both component cells could justify lower values with the use of a model to be defined. The application of the mismatch by tuning the solar simulator would result in a lower uncertainty regarding the spectrum (V in Table II). But we estimate an upper limit for neglecting the mismatch with a worst cast analysis.

Therefore we have high confidence in the declaration of the expanded uncertainty (k=2) u95=2.9% in the maximum electrical power at standard test conditions.

Although only certain embodiments of this invention have been described in detail above, those skilled in the art will readily appreciate that many modifications are possible in the embodiments without materially departing from the novel teachings and advantages of this invention. Accordingly, all such modifications are intended to be included within the scope of this invention.

1. A method of measuring a current-voltage (IV) characteristic for a photovoltaic (PV) device, comprising:
providing a PV module for measuring an IV characteristic;
exposing said PV module to a solar electromagnetic (EM) spectrum;
performing a first set of measurements that includes acquiring plural IV segments by applying and sweeping a voltage across the PV module beginning from a first series of unique initial voltages and ending at a first target voltage within a pulse plateau for exposing said PV module to said solar EM spectrum; and
measuring and recording a first IV data point on said IV characteristic that includes a first current for said PV module at said first target voltage if convergence of said plural IV segments in said first set of measurements occurs at said first target voltage.

2. The method of claim 1, further comprising:
acquiring another IV data point on said IV characteristic by repeating said performing and measuring for another target voltage.

3. The method of claim 1, further comprising:
acquiring a series of IV data points on said IV characteristic by repeating said performing and measuring for a series of target voltages.

4. The method of claim 3, further comprising:
characterizing said PV module by calculating PV module power or further assembling said IV characteristic using said series of IV data points.

5. The method of claim 3, further comprising:
computing power for said PV module using each IV data point recorded in said series of IV data points; and
determining a maximum power output from said PV module.

6. The method of claim 3, further comprising:
fitting a data curve to said series of IV data points.

7. The method of claim 1, wherein said sweeping a voltage across the PV module from a unique initial voltage to a target voltage comprises sweeping a voltage across a voltage range within plus or minus 10V of said target voltage.

8. The method of claim 1, wherein said sweeping a voltage across the PV module from a unique initial voltage to a target voltage comprises sweeping a voltage across a voltage range within plus or minus 2V of said target voltage.

9. The method of claim 1, wherein said sweeping a voltage across the PV module from a unique initial voltage to a target voltage comprises sweeping a voltage across a voltage range within plus or minus 1V of said target voltage.

10. The method of claim 1, wherein said exposing said PV module to said solar electromagnetic (EM) spectrum comprises flashing said PV module with EM pulses at a pulse time less than or equal to 50 milliseconds.

11. The method of claim 1, wherein said exposing said PV module to said solar electromagnetic (EM) spectrum comprises flashing said PV module with EM pulses at a pulse time less than or equal to 20 milliseconds.

12. The method of claim 1, wherein said exposing said PV module to said solar electromagnetic (EM) spectrum comprises flashing said PV module with EM pulses at a pulse time less than or equal to 10 milliseconds.

13. The method of claim 12, wherein said sweeping a voltage across the PV module from a unique initial voltage to a target voltage comprises sweeping a voltage across a voltage range within plus or minus 1V of said target voltage at a voltage sweep rate of 100 V/second or greater.

14. The method of claim 1, wherein characterization of said PV module is performed with an uncertainty of less than or equal to 3%.

15. The method of claim 1, wherein said PV module comprises a crystalline silicon PV module, a thin film PV module, or a hetero-junction PV module.
